(19) United States
(12) Patent Application Publication
(10) Pub. No.: US 2020/0240011 A1
(43) Pub. Date: Jul. 30, 2020

(54) COATING OF AN OBJECT

(71) Applicant: AALTO UNIVERSITY FOUNDATION SR, AALTO (FI)

(72) Inventors: Christoffer KAUPPINEN, Espoo (FI); Kirill ISAKOV, Espoo (FI); Sami FRANSSILA, Espoo (FI)

(21) Appl. No.: 16/650,159

(22) PCT Filed: Oct. 1, 2018
(86) PCT No.: PCT/FI2018/050706

§ 371 Date: Mar. 24, 2020

(30) Foreign Application Priority Data
Oct. 11, 2017 (FI) 20175890

(51) Int. Cl. C23C 16/40; C23C 16/455; C23C 16/56; B05D 1/00

(52) U.S. Cl. CPC C23C 16/403; C23C 16/45525; C23C 16/56; B82Y 30/00; C23C 16/402; C23C 16/405; B05D 2506/10; B05D 1/62

(57) ABSTRACT

The object of the invention is to provide an improved coating. The coating comprises a high transmittance antireflection layer of a grass-like alumina made by atomic layer deposition technique and subsequent water immersion. The coating also comprises at least one coating layer on the layer of a grass-like alumina, an uppermost coating layer being a low-surface energy coating. The coating is also hydrophobic and transparent.

### FIELD OF TECHNOLOGY

The invention relates to coatings of an object. The object can be any object which is desired to be coated like camera lenses, the cover glass or front glass of a solar cell, the cover glass or front glass of a solar module, the cover glass or front glass of a solar panel, window glass, wind shield glass in cars or other transport, glass or plastic covering devices or dashboards, display glass, a microfluidic component like a channel or a capillary, photonic waveguides, plastic parts, packaged or unpackaged integrated circuits, photodetectors, unpackaged or protected electronic or optoelectronic devices like unpackaged photodetectors, finished electronic goods like watches or parts of them, Fresnel lenses, axicons, gratings etc. Especially the invention relates to a grass-like alumina coating, which is a relatively new coating.

### PRIOR ART

It is known to make a coating on an object like a camera lens in order to achieve water-repellent properties. Water-repellent coatings can be useful for many applications such as corrosion protection in metal parts or non-wetting glass. Often water-repellent or hydrophobic surfaces are fabricated by constructing a high-surface area substrate and coating this with a low-surface energy coating.

A grass-like alumina coating is a relatively new coating, that functions as an optical antireflection coating with broadband and omnidirectional optical transmittance. The grass-like alumina is made by atomic layer deposition (ALD) technique and subsequent immersion into hot water. The fabrication of the grass-like alumina has been published in 2017.

It is also known to use a sol-gel method for fabricating a hydrophobic alumina coating. The coating produced by the sol-gel method differs from the grass-like alumina deposited by ALD, for example having a different composition of the initial alumina. Further, the coating of the sol-gel method is not so conformal as the grass-like alumina coating and the sol-gel process is often limited by the necessity for high temperatures during the coating thus damaging many objects or materials.

Although, the current coatings provide good properties, improvements of the coatings are seeked.

### SHORT DESCRIPTION

The object of the invention is to improve the coating properties. The object is achieved in a way described in the independent claims. Dependent claims illustrate different embodiments of the invention.

The coating of an object according to the invention comprises antireflection layer of a grass-like alumina made by atomic layer deposition technique and subsequent hot water immersion. The grass-like alumina antireflection coating has good broadband and omnidirectional transmittance. The coating also comprises at least one coating layer on the layer of a grass-like alumina, an uppermost coating layer being a low-surface energy coating. The uppermost coating layer can be plasma enhanced chemical vapour deposition coated fluoropolymer or parylene. The upper most coating layer can be any low surface energy coating. The finished coating is hydrophobic or superhydrophobic depending on the processing. The coating can also have high broadband optical transmittance depending on the number and type of intermediate coating layers, and depending on the type and thickness of the uppermost coating.

### LIST OF FIGURES

In the following, the invention is described in more detail by reference to the enclosed drawings, where

FIG. 1 illustrates an example of a coating according to the invention.

### DESCRIPTION OF THE INVENTION

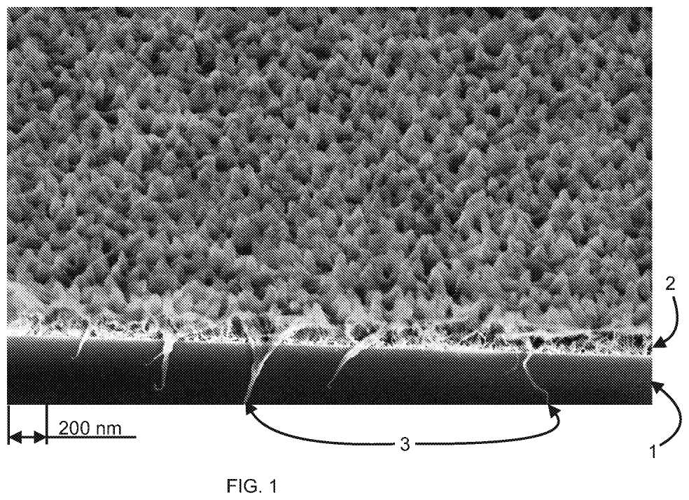

FIG. 1 illustrates an example of a coating according to the invention. FIG. 1 is a SEM (scanning electron microscopy) image of the cross section of an object coated with the coating according to the invention. An object 1, for example a lens, has been coated by a grass-like alumina 2 using atomic layer deposition and hot water immersion. Atomic layer deposition (ALD) is a film deposition technique wherein the film is thin. The ALD technique is based on the sequential use of a gas phase chemical process. As said above the ALD technique combined with subsequent immersion into hot water can be used to perform the grass-like alumina 2 providing certain features. As can be seen the grass-like alumina has high surface area providing roughness that is advantageous in view of water-repellent properties.

The topography of the grass-like alumina layer is also unique and advantageous in order to have very good antireflection features specifically very good broadband transmittance and omnidirectional transmittance.

The coating of FIG. 1 comprises also a coating layer 3 on the grass-like alumina 2, where coating layer 3 is a low-surface energy coating. Together the low-surface energy coating and the grass-like alumina provides very good water-repellent and hydrophobic properties, much better than either alone. In this text the inventive coating is also called hydrophobic alumina nanograss (HAN). It can be also noted in FIG. 1 that the coating is very conformal.

So, the grass-like alumina alone or the uppermost coating alone does not need to provide water repellent or hydrophobic properties. However, the inventive combination provides these properties, in other words the combination of a coating having high roughness and a coating having low surface energy provides very good water repellent and/or hydrophobic properties.

Surface energy quantifies the disruption of intermolecular bonds that occur when a surface is created. The molecular force of attraction between different materials determinates their adhesion. Low surface energy means weak attractive forces and high surface energy means strong attractive forces. So, in practice contact angle measurements can be used to determine the surface energy. Here a water drop is placed on the surface of a material. The contact angle is 0 degrees when the water completely wets the substrate. (The drop is flat.) If the angle is 180 degrees, the liquid does not wet the substrate at all. (The drop has only one contact point with the material.) So, the low surface energy means higher contact angles. The water contact angle of the inventive coating is higher than 90 degrees and can be at range 172-176 degrees, but the range can also be larger i.e. 172 degrees or more. The water contact angle depends on an inventive application produced.

Since the water angle must be at least 150 degrees in order to have superhydrophobic surface, the invention can also provide a superhydrophobic coating. The nanoscale roughness of grass-like alumina gives grass-like alumina a very high surface area which produces good water repellent properties when coated with a low surface energy coating. By adding the low-surface energy coating that suits with the grass-like alumina the hydrophobicity features are also obtained in such a way that said hydrophobic coating (HAN) is achieved. So, the grass-like alumina and the low-surface energy coating together provides very good water-repellent and hydrophobic properties, much better than either alone.

HAN can be deposited on any surface where the grass-like alumina can be made and which then can be coated with the low surface energy coating. The grass-like alumina is known to have excellent conformality. Such conformality is very beneficial in applications where the object to be coated has complex topography. So, the coating can be deposited on all surfaces regardless of shape, for example Fresnel lenses, axicons, gratings, curved camera lenses etc. Conformal deposition enables massive scalability, so hundreds of components of any shape can be coated simultaneously. So, the HAN can also be conformal depending on the process how it is made. So, processes of making the uppermost layer and possible intermediate layers affect the conformality properties.

The HAN has excellent hydrophobicity, even superhydrophobicity or ultrahydrophobicity, depending on how the grass-like alumina was made. The low surface energy coating can be made from any suitable material that suits well to be used with the grass-like alumina. For example plasma enhanced chemical vapour deposition (PECVD) coated fluoropolymer can be used. In this embodiment CHF3 plasma can be used. PECVD complements the grass-like alumina process well as it enables as low or lower temperatures as the grass-like alumina process, thus enabling temperature sensitive materials to be coated. Another example of the low surface energy coating is parylene, like parylene-C, which can be deposited at low temperatures extremely conformally like the initial grass-like alumina. Further examples of the low surface energy coatings are low surface energy self-assembled monolayers, fluorocarbon layers, silane layers, or branched hydrocarbon layers.

The HAN is typically extremely transparent, as typically all the layers have high transparency It can be manufactured in a low temperature process, so the process of manufacturing the HAN differs from known processes (like temperatures, precursors and parameters). The process temperature for depositing the initial ALD alumina for making the grass-like alumina can be 120 degrees Celsius. However even room temperature is possible for the process.

The HAN is also versatile as it can be deposited on materials where atomic layer deposition (ALD) alumina can be deposited. The deposition on any suitable object is possible. The material of the object can be for example glass, metals or plastics like PS, PP, PMMA, PE, or PVC. When the grass-like alumina and the subsequent low-surface energy coating are fabricated the result is hydrophobic or even superhydrophobic. The topography of the HAN also differs from known coatings.

The grass-like alumina as such has very good omnidirectional broadband transmission properties and antireflection properties. For example, the anti-reflective properties of the HAN coating is good for any transparent solid materials with refractive index of in range 1.4-1.8, for example about 1.5.

The suitable low surface energy coating on the grass-like alumina (in other words the HAN coating) does not decrease, transparency, antireflection and transmission properties in applications of the invention. However, some applications may have a minor decrease of transparency, antireflection and/or transmission properties if designed that way, like having several intermediate layers for achieving other properties, for example durability.

HAN can in some instances be prepared such, that there is an intermediate coating or coatings between the grass-like alumina and the low surface-energy coating, the function of this intermediate coating depends on the specific embodiment, but can for example be used to modify adhesion of the grass-like alumina or change the surface topography by coating the grass-like alumina. An example of such an intermediate coating is a thin titania layer deposited with atomic layer deposition, a nanolaminate of alumina and titania, or SiO₂. SiO₂ can be deposed by ALD. An additional chemical stability and extra stiffness is achieved.

It is evident from the above that the invention is not limited to the embodiments described in this text but can be implemented in many other different embodiments within the scope of the independent claim.

1. A coating of an object, which coating comprises a transparent layer of a grass-like alumina made by atomic layer deposition technique and subsequent immersion to hot water, characterised in that the coating also comprises at least one coating layer on the layer of a grass-like alumina, an uppermost coating layer being a low-surface energy coating, the coating being transparent and also being hydrophobic or superhydrophobic.

2. A coating of an object according to claim 1, characterised in that the coating is a high broadband and omnidirectional optical transmittance antireflection coating.

3. A coating of an object according to claim 1, characterised in that the uppermost coating layer is plasma enhanced chemical vapour deposition coated fluoropolymer or parylene.

4. A coating of an object according to claim 3, characterised in that the said parylene is parylene-C.

5. A coating of an object according to claim 1, characterised in that the coating is conformal.

6. A coating of an object according to claim 1, characterised in that the water contact angle of the coating is 90 degrees or more.

7. A coating of an object according to claim 1, characterised in that the water contact angle of the coating is 172-176 degrees.

8. A coating of an object according to claim 1, characterised in that the between the uppermost layer of the low-surface energy coating and the grass-like alumina there is a titania layer deposited by atomic layer deposition.

9. A coating of an object according to claim 1, characterised in that the between the uppermost layer of the low-surface energy coating and the grass-like alumina there is a layer of a nanolaminate of alumina and titania.

10. A coating of an object according to claim 1, characterised in that the between the uppermost layer of the low-surface energy coating and the grass-like alumina there is a SiO₂ layer deposited by atomic layer deposition.
